(19) United States
(12) Patent Application Publication
(10) Pub. No.: US 2006/0051912 A1
(43) Pub. Date: Mar. 9, 2006

(54) Method and apparatus for a stacked die configuration

(75) Inventor: Vincent K. Chan, Richmond Hill (CA)

Correspondence Address: ATI TECHNOLOGIES, INC.;C/O VEDDER PRICE KAUFMAN & KAMMHOLZ, P.C., 222 N.LASALLE STREET, CHICAGO, IL, 60601, US

(73) Assignee: ATI Technologies Inc., Markham (CA)

(21) Appl. No.: 10/938,439

(22) Filed: Sep. 9, 2004

(51) Int. Cl. H01L 21/84

(52) U.S. Cl. 438/166

(57) ABSTRACT

A stacked die configuration for use in an IC package includes a first IC die mechanically coupled to a substrate material. Mechanically coupled to the first IC die is an interposer having an aperture adapted to receive a second IC die. Mechanically coupled to the first IC die and fitting within the aperture of the interposer is a second IC die. As a result, both the overall height of the IC package and the length of the bond wires connecting each of the members of the stacked die configuration may be reduced.

### FIELD OF THE INVENTION

The invention relates generally to a method and apparatus for integrated circuit (“IC”) stacked die configurations, and more particularly to IC stacked die configurations that decrease the total height of the package and further decrease the length of bond wires.

### BACKGROUND OF THE INVENTION

IC packages, such as semiconductor packages, may include an IC die mounted to a substrate material. The trend in packaging is to combine several IC dice into one package to save space, increase modularity and decrease packaging costs. With the advent of mobile electronic devices such as cell phones and personal digital assistants (“PDAs”), various stacked die configurations have been proposed essentially attaching two or more IC dice on top of a substrate.

In conventional configurations, a first IC die is attached to a substrate material using a die adhesive or other die bonding technique. A second IC die is then attached to the top of the first IC die also using a die adhesive or other die bonding technique. Wire bonding techniques then establish contact between each IC die and the substrate material. As a result, wire bonds connect one set of electrical contact pad surfaces of the substrate to electrical contact pad surfaces of the first IC die. Similarly, wire bonds connect a second set of electrical contact pad surfaces of the substrate to electrical contact pad surfaces of the second IC die. As used throughout this disclosure and claims, the term “electrical contact pad surfaces” is synonymous with the term “bond pads.”

Conventional configurations, however, suffer from multiple drawbacks, especially when a top IC die is of a much smaller size than a bottom IC die. The primary drawback is a result of the length of the bond wires extending from the top IC die to the substrate material. This problem is made worse when electrical contact pad surfaces are not located near the edge of the top IC die. In addition to adding unnecessary height to the configuration, the long bond wires can introduce more noise and may decrease reliability.

As a first prior art solution, additional electrical contact pad surfaces are provided on the top surface of the bottom IC die near an edge of the top IC die. Because one goal is to limit the length of each bond wire and further because the top IC die is often much smaller in size than the bottom IC die, bond pads are typically placed away from the edge of the bottom IC die. As a result, the bond pads are often disposed over active circuits and cause additional electrical interference and unwanted noise. Therefore, this solution is undesirable due to the inherent electrical problems that can result in disposing bond pads away from an edge of the bottom IC die, a location where active circuits are traditionally positioned.

A second prior art solution is to provide a solid interposer substrate as a member of the stacked die configuration between the two IC dice. An interposer is preferably composed of a substrate material similar or equivalent in composition to the original substrate material to which the bottom IC die is mounted. The interposer is mounted between the two IC dice utilizing a die adhesive or other die mounting technique.

The interposer typically has two sets of bond pads, wherein bond wires connect the first set of bond pads of the interposer to a second set of bond pads of the bottom IC die and wherein bond wires connect the second set of bond pads of the interposer to a first set of bond pads on the top IC die. To maintain electrical contact with the substrate material, wire bonds connect a first set of bond pads of the bottom IC die to bond pads of the substrate material.

This solution removes the problem associated with adding additional bond pads over active circuits of the bottom IC die and more importantly decreases the length of each bond wire. However, the interposer adds undesired height to the IC package.

A third prior art solution is to invert the positions of each die in a stacked die configuration. Instead of having the largest IC die on the bottom of the stack, this solution calls for the smallest IC die on the bottom and the largest IC die to be on the top of the stack. With the IC dice mounted in an inverted pyramid, this solution creates a large overhang of the top IC die over the bottom IC die. After each IC die is affixed, bond wires individually connect bond pads of each member to bond pads of the substrate material. While this solution does not use an interposer, and therefore does not add unnecessary height to the IC package, wire bondability can limit the overhang length, measured from the bond pads of the substrate to the bond pads of the top IC die, to about 2 mm.

Although stacked die configurations may contain numerous die members (i.e., more than two IC dice), examples provided throughout this specification are limited to examples with only two IC dice, a top die and a bottom die, for ease of discussion.

Therefore, a need exists to create a stacked die configuration that limits the overall height of the IC package while also limiting the length of bond wires used to connect each die to the substrate material.

### BRIEF DESCRIPTION OF THE DRAWINGS

The invention will be more readily understood in view of the following description when accompanied by the below figures and wherein like reference numerals represent like elements:

FIG. 1 is a plan view illustrating a conventional stacked die configuration in accordance with the prior art;

FIG. 2 is a sectional view of FIG. 1 further illustrating the bond wires of the stacked die configuration;

FIG. 3 is a plan view illustrating a stacked die configuration utilizing an interposer in accordance with the prior art;

FIG. 4 is a sectional view of FIG. 3 further illustrating the bond wires of the stacked die configuration with interposer;

FIG. 5 is a plan view illustrating one example of a stacked die configuration in accordance with one embodiment of the present invention;

FIG. 6 is a sectional view of FIG. 5 further illustrating the bond wires of the stacked die configuration of FIG. 5;

FIG. 7 is a flow chart illustrating a method of making an integrated circuit package in accordance with one embodiment of the present invention; and

FIG. 8 is a flow chart illustrating a method of making an integrated circuit package in accordance with one embodiment of the present invention.

### DETAILED DESCRIPTION OF A PREFERRED EMBODIMENT

Generally, a stacked die configuration is disclosed that reduces the height of the overall IC package and further reduces the length of bond wires by employing an interposer with an aperture therein. In one embodiment, a bottom IC die is mechanically coupled to a substrate material. An interposer having an aperture adapted to receive a top IC die is mechanically coupled on top of the bottom IC die. Similarly, a top IC die is mechanically coupled to the top of the bottom IC die to fit within the aperture of the interposer. Bond wires then connect bond pads of the substrate material to similar pads of the bottom IC member. Bond wires also connect bond pads of the bottom IC die to bond pads of the interposer. Lastly, bond wires connect bond pads of the interposer to the bond pads of the top IC die.

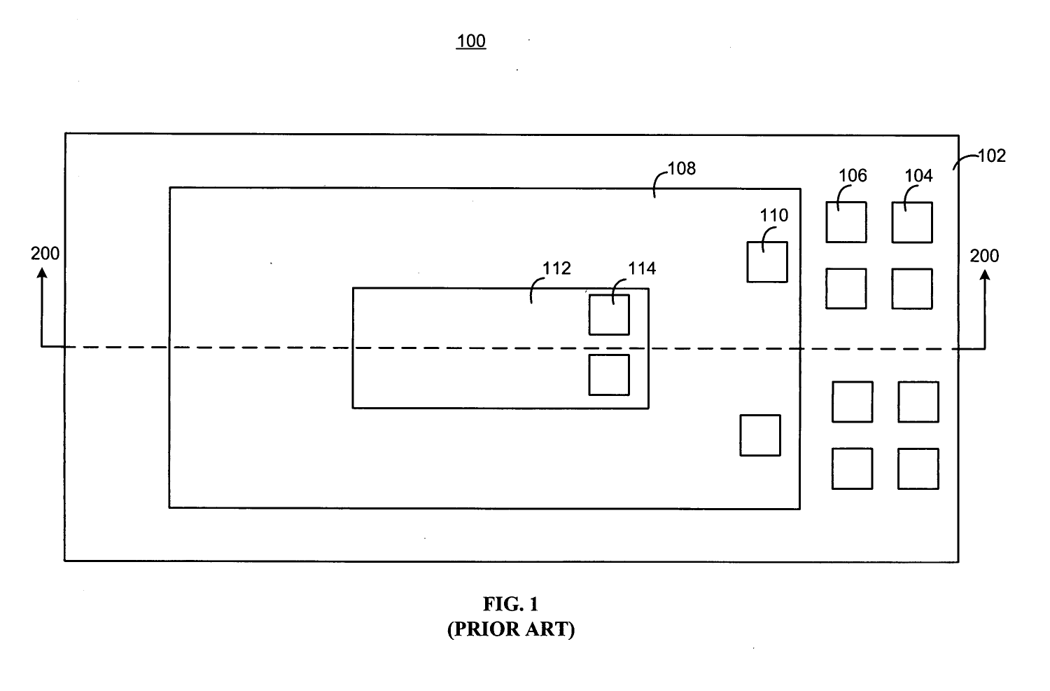

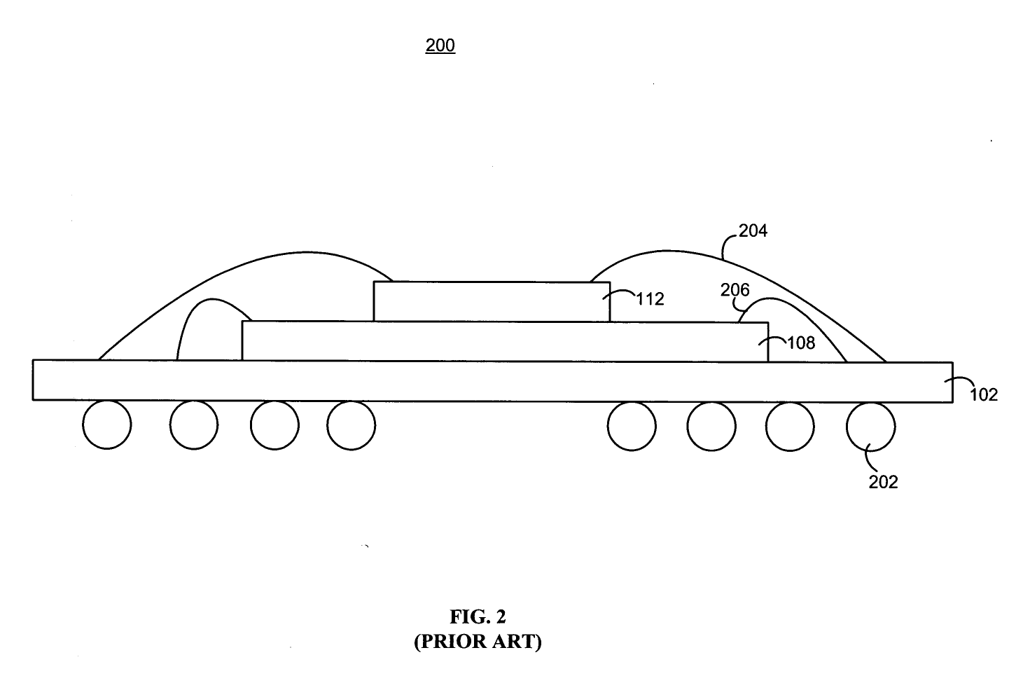

Referring now to FIG. 1, a plan view illustrates the structure of a conventional stacked die configuration 100 in accordance with the prior art. The stacked die configuration 100 includes a substrate material 102 made of, for example, bizmalemide triazine, or any other suitable material. The substrate material 102 includes two sets of electrical contact pad surfaces, a first set of bond pads 104 and a second set of bond pads 106. Affixed to the substrate material 102 using die adhesive or another suitable bonding technique is a first IC die 108 also containing a set of bond pads 110. Lastly, a second IC die 112 is affixed to the first IC die 108 also using a die adhesive or other suitable bonding technique. The second IC die 112 includes a single set of bond pads 114. Reference line 200 illustrates the viewpoint of the section view of FIG. 2.

Turning to FIG. 2, a section view with respect to reference line 200 of FIG. 1 illustrates the spatial relationship and electrical connection of each die with respect to the substrate material 102. Additionally, a plurality of solder balls 202 are disposed along the bottom side of a substrate material 102 for mounting to a mother board or other element of a larger electrical network. Wire bond 204 illustrates the electrical connection between the first set of bond pads 104 (shown in FIG. 1) of the substrate material 102 and the bond pads 114 of the second IC die 112. Similarly, wire bond 206 illustrates the electrical connection between the second set of bond pads 106 (shown in FIG. 1) of the substrate material 102 and bond pads 110 (shown in FIG. 1) of the first IC die 108.

As mentioned earlier, the stacked die configuration of FIGS. 1 and 2 demonstrate the undesirable length of wire bonds that are necessary when a top IC die is substantially smaller than a bottom IC die in stacked configurations.

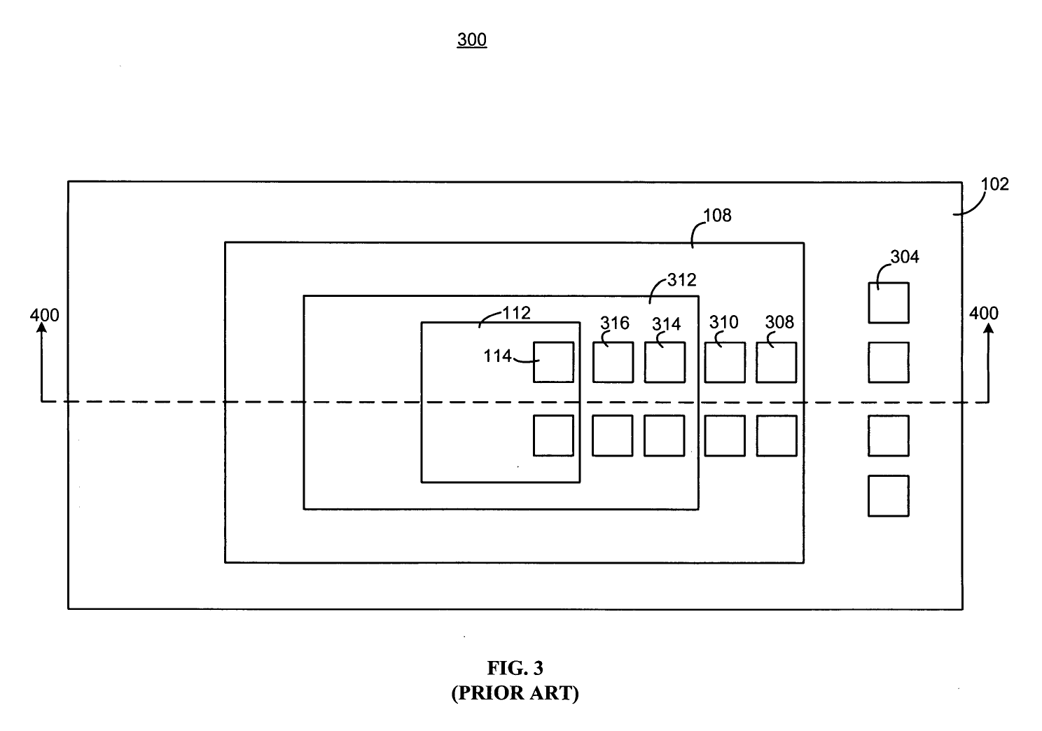

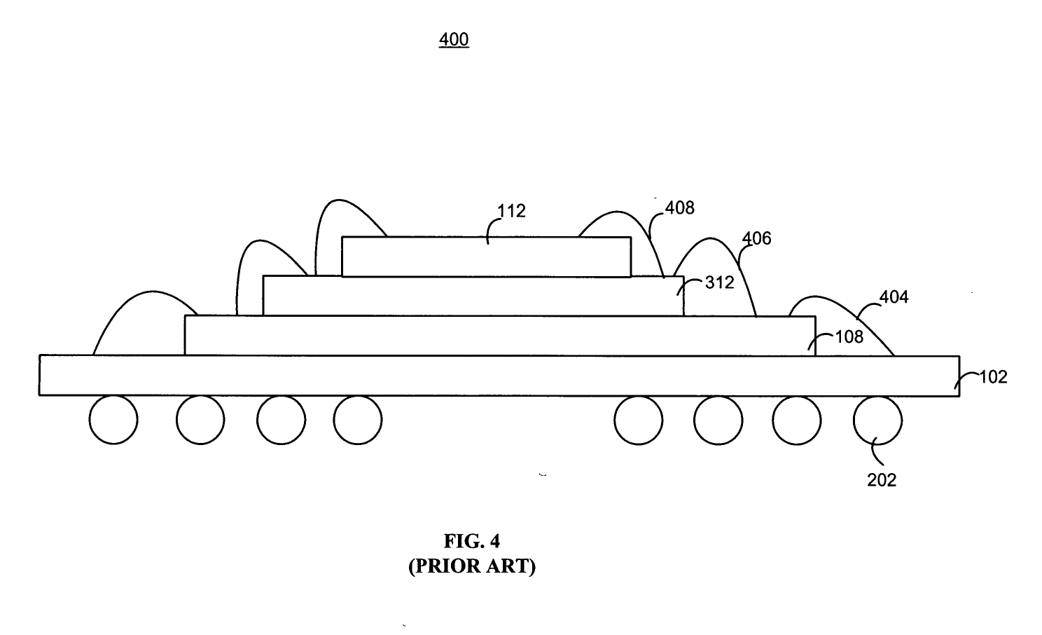

FIG. 3 illustrates a prior art structure that includes an interposer 312 between the first IC die 108 and the second IC die 112. The first IC die 108, affixed to a substrate material 102, includes a first set of bond pads 308 and a second set of bond pads 310. The interposer 312 is affixed on top of the first IC die 108 and is preferably of a smaller size than the first IC die 108. The interposer 312 includes a first set of bond pads 314 and a second set of bond pads 316. Lastly, a second IC die 112 is affixed on top of the interposer 312 and is preferably of a smaller size than the interposer 312. The second IC die 112 includes a single set of bond pads 114. For purposes of further discussion, reference line 400 is superimposed over the stacked die configuration 300 to illustrate the viewpoint of the section view in FIG. 4.

As stated, FIG. 4 is a section view of the stacked die configuration with respect to reference line 400 of FIG. 3. The section view shows, among other things, the spatial relationships and lines of electrical communication between each IC die 108 and 112, the interposer 312 and the substrate material 102. Additionally, the section view illustrates a plurality of solder balls 202 disposed on the bottom surface of the substrate material 102 for connection in a mother board or larger electrical network.

Wire bond 404 connects the set of bond pads 304 (shown in FIG. 3) of the substrate material 102 to the first set of bond pads 308 (shown in FIG. 3) of the first IC die 108. Wire bond 406 connects the second set of bond pads 310 (shown in FIG. 3) of the first IC die 108 to the first set of bond pads 314 (shown in FIG. 3) of the interposer 312. Lastly, wire bond 408 connects the second set of bond pads 316 (shown in FIG. 3) of the interposer 312 to the set of bond pads 114 (shown in FIG. 3) of the second IC die 112. As illustrated, each wire bond has decreased in length with respect to the prior art solutions of FIGS. 1 and 2, but as a result, the total height of the IC package has increased due to the interposer 312.

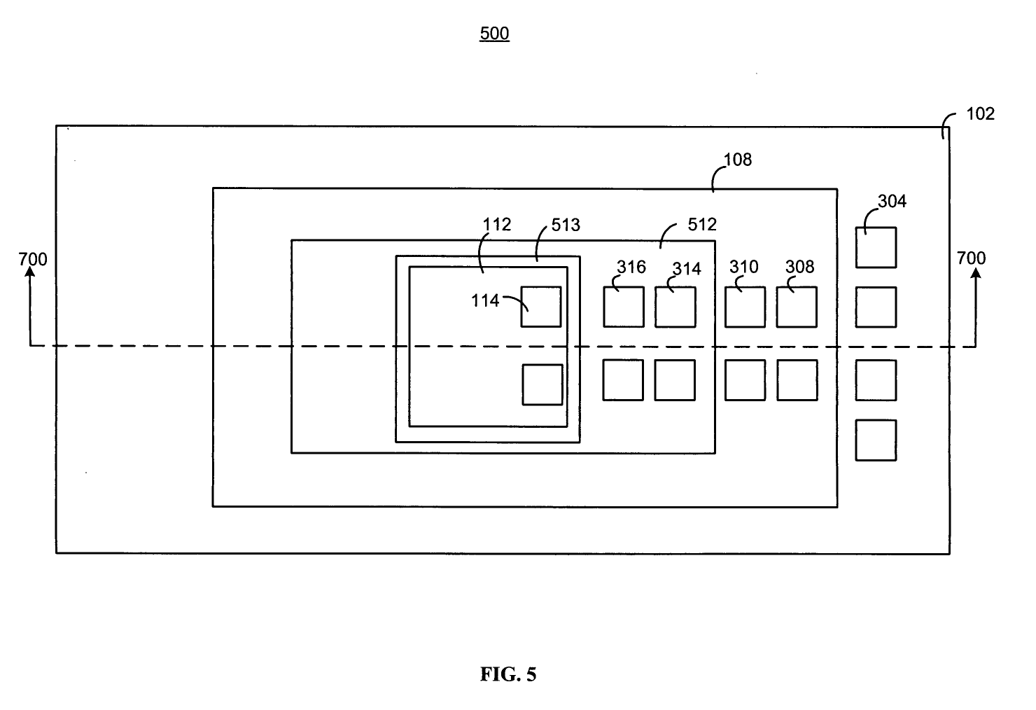

Referring now to FIG. 5, one embodiment of the present invention is illustrated depicting a plan view of a stacked die configuration 500. A first IC die 108 is mechanically coupled, directly or indirectly to a substrate material 102. In one embodiment, the first IC die 108 is mounted directly on top of the substrate 102 using die adhesive or another suitable die bonding technique. The substrate material 102 includes a set of bond pads 304. The first IC die 108 comprises a first set of bond pads 308 and a second set of bond pads 310. Mechanically coupled, directly or indirectly, to the first IC die 108 is an interposer 512 having an aperture 513 adapted to receive a second IC die 112. In one embodiment, the interposer 512 is bonded to the first IC die 108 using a die adhesive or other suitable die bonding technique. Additionally, the interposer 512 is composed of the same or similar material as the substrate material 102. Additionally, the interposer 512 is preferably of a smaller size than the first IC die 108, but of a larger size than the second IC die 112.

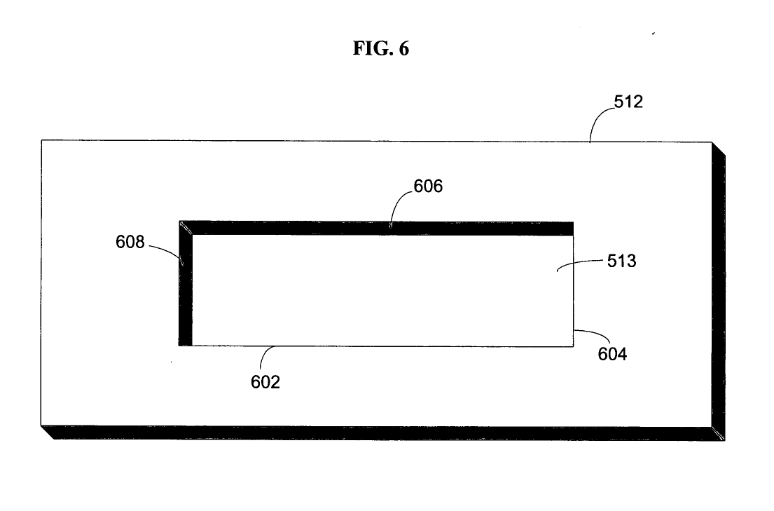

The interposer 512 further includes a first set of bond pads 314 and a second set of bond pads 316. Also mechanically coupled, directly or indirectly, to the first IC die 108 and fitting within the aperture 513 is a second IC die 112. In one embodiment, the second IC die 112 is mounted using a bond adhesive or other suitable die bonding technique and further includes a single set of bond pads 114. Lastly, FIG. 5 includes reference line 700 illustrating the viewpoint corresponding to the section view of FIG. 6.

Because each member of the stacked die configuration 500 can be mechanically and electrically coupled to another member either directly or indirectly, this disclosure recognizes that an additional layer or layers may be inserted as one or more intervening layers between each member of the stacked die configuration 500.

In one embodiment, the aperture 513 is defined by four walls as shown in FIG. 6 by walls 602-608 of the interposer 512. However, it will be recognized that the aperture 513 may take any geometric shape. It is further acknowledged that in one embodiment, the aperture 513 has a shape corresponding to the shape of the second IC die 112.

As described above, the aperture 513, in one embodiment, is defined to include one or more side walls that collectively serve as a pass-through to the underlying member of the stack 500, the first IC die 108. However, in a second embodiment, it is also recognized that the aperture 513 may be defined by one or more side walls and a base that serve as a well within the interposer 512. It is further recognized that in yet another embodiment, the aperture 513 may be defined by one or more side walls and a base that serve as a well with one or more openings in the base of the well exposing the underlying member of the stack 500, the first IC die 108. While the shape of the substrate 102, the first IC die 108, the interposer 512 and the second IC die 112 are illustrated as parallelograms, it will be recognized that they may take any geometric form including, but not limited to, triangles and circles.

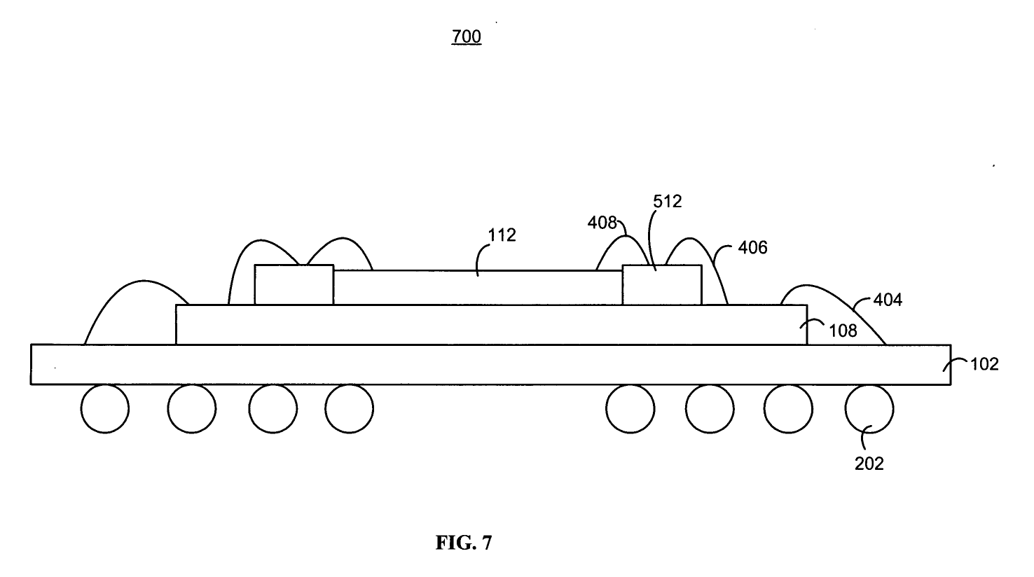

Turning to FIG. 7, a section view with respect to reference line 700 of FIG. 5, illustrates the channels of electrical communication between each member of the stack 700. The section view also illustrates the plurality of solder balls 202 for use in connection to a mother board or larger electrical network. The stacked die configuration 700 of FIG. 7 illustrates wire bond 404 connecting the bond pads 304 (shown in FIG. 5) of the substrate material 102 to the first set of bond pads 308 (shown in FIG. 5) of the first IC die 108. Similarly, wire bond 406 illustrates the connection between the second set of bond pads 310 (shown in FIG. 5) of the first IC die 108 and the first set of bond pads 314 (shown in FIG. 5) of the interposer 512. Lastly, wire bond 408 illustrates the connection between the second set of bond pads 316 (shown in FIG. 5) of the interposer 512 and the bond pads 114 (shown in FIG. 5) of the second IC die 112.

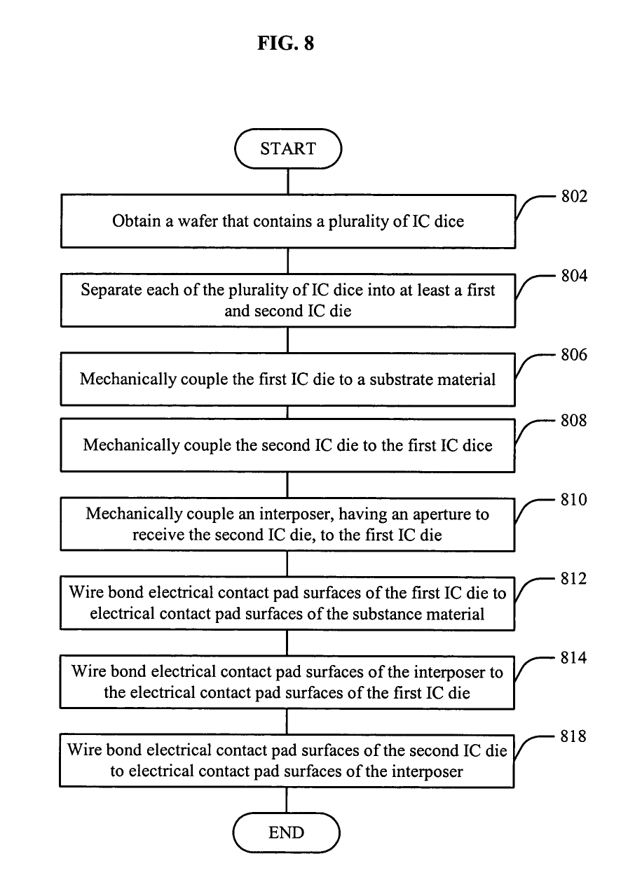

Turning to the method by which one embodiment of the present invention is manufactured, FIG. 8 illustrates a flow chart of each step in the process. The method begins with step 802 where a wafer is obtained, such as by a suitable mechanism containing a plurality of IC dice. The process continues to step 804 where each of the plurality of IC dice is separated into at least a first and a second IC die using well known techniques in the art. In step 806, the first IC die is mechanically coupled to a substrate material using a die adhesive or any suitable die bonding technique. In step 808, a second IC die is mechanically coupled to the first IC die utilizing a similar method. Lastly, in step 810, an interposer, having an aperture to receive the second IC die, is mechanically coupled to the first IC die such that the second IC die is fit within the aperture of the interposer.

In step 812, wire bonds connect electrical contact pad surfaces or bond pads of the first IC die to similar bond pads of the substrate material. In step 814, wire bonds connect bond pads of the interposer to similar bond pads of the first IC die. Lastly, in step 816, wire bonds connect bond pads of the interposer to similar bond pads of the second IC die.

While FIG. 8 illustrates the method of manufacture in the individual sequential steps 802-818, the present invention does not limit the method to this recited sequence. In contrast, this disclosure recognizes the interchangeability of the steps such that each IC die, interposer and substrate material is both affixed to one another and in electrical communication with one another.

As illustrated above, the bond wires of FIG. 7 are shorter than the bond wires shown in the prior art solutions. Additionally, the overall height of the IC package illustrated in FIGS. 5 and 7 is less than the height in prior art solutions. As a result, the present invention, among other things, meets the need associated with the manufacture of modern electrical components and devices. Simultaneously, the disclosure illustrates the manner by which multiple IC dice can be stacked to save space, decrease costs, and further decrease electrical problems associated with long bond wires.

While FIGS. 1-6 have been described with respect to a pre-determined number of bond pads per member in the stacked die configuration, it is acknowledged that the present invention includes any number of bond pads per stacked die member as required to achieve connectivity between each die, interposer and the substrate. In fact, it is recognized that if the bond pads are large enough, more than one wire bond can bond to the same pad, thereby reducing the number of sets of bond pads per member as previously discussed.

Although stacked die configurations may contain numerous die members (i.e., more than two IC dice), descriptions provided throughout this disclosure are limited to examples with only two IC die, a top and a bottom die, for ease of discussion only and is not meant to limit the invention. The above detailed description of a preferred embodiment and the examples described therein have been presented for the purposes of illustration and description only and not by limitation. It is therefore contemplated that the present invention cover any and all modifications, variations or equivalents that fall within the spirit and scope of the basic underlying principles disclosed above and claimed herein.

What is claimed:

1. A method of making an integrated circuit package comprising:
mechanically coupling a first integrated circuit die to a substrate material;
mechanically coupling a second integrated circuit die of a smaller size than the first integrated circuit die to the first integrated circuit die; and
mechanically coupling an interposer, having an aperture adapted to receive the second integrated circuit die, to the first integrated circuit die.

2. The method of claim 1 further comprising:
obtaining a wafer that contains a plurality of integrated circuit dies;
separating each of the plurality of integrated circuit dies from the wafer into at least the first integrated circuit die and the second integrated circuit die.

3. The method of claim 1 further comprising:
wire bonding electrical contact pad surfaces of the first integrated circuit die to electrical contact pad surfaces of the substrate material;
wire bonding electrical contact pad surfaces of the interposer to electrical contact pad surfaces of the first integrated circuit die; and
wire bonding electrical contact pad surfaces of the second integrated circuit die to electrical contact pad surfaces of the interposer.

4. The method of claim 1, wherein the method of mechanically coupling the first integrated circuit die to the substrate material includes applying a die adhesive to at least one of the first integrated circuit die and the substrate material.

5. The method of claim 1, wherein the method of mechanically coupling the second integrated circuit die to the first integrated circuit die includes applying a die adhesive to at least one of the second integrated circuit die and the first integrated circuit die.

6. The method of claim 1, wherein the method of mechanically coupling the second integrated circuit die to the interposer includes applying a die adhesive to at least one of the second integrated circuit die and the interposer.

7. The method of claim 1, wherein the height of the interposer is greater than or equal to the height of the second integrated circuit die.

8. An integrated circuit package made by the process of at least:
mechanically coupling a first integrated circuit die to a substrate material;
mechanically coupling a second integrated circuit die of a smaller size than the first integrated circuit die to the first integrated circuit die; and
mechanically coupling an interposer, having an aperture adapted to receive the second integrated circuit die, to the first integrated circuit die.

9. The integrated circuit package of claim 8 further made by the process of:
wire bonding electrical contact pad surfaces of the first integrated circuit die to electrical contact pad surfaces of the substrate material;
wire bonding electrical contact pad surfaces of the interposer to electrical contact pad surfaces of the first integrated circuit die; and
wire bonding electrical contact pad surfaces of the second integrated circuit die to electrical contact pad surfaces of the interposer.

10. The integrated circuit package of claim 8, wherein the method of mechanically coupling the first integrated circuit die to the substrate material includes applying a die adhesive to at least one of the first integrated circuit die and the substrate material.

11. The integrated circuit package of claim 8, wherein the method of mechanically coupling the second integrated circuit die to the first integrated circuit die includes applying a die adhesive to at least one of the second integrated circuit die and the first integrated circuit die.

12. The integrated circuit package of claim 8, wherein the method of mechanically coupling the second integrated circuit die to the interposer includes applying a die adhesive to at least one of the second integrated circuit die and the interposer.

13. The integrated circuit package of claim 8, wherein the height of the interposer is greater than or equal to the height of the second integrated circuit die.

14. An integrated circuit package comprising:
a first integrated circuit die mechanically coupled to a substrate material;
a second integrated circuit die, having a smaller size than the first integrated circuit die, mechanically coupled to the first integrated circuit die;
an interposer, having an aperture adapted to receive the second integrated circuit die, mechanically coupled to the first integrated circuit die.

15. The integrated circuit package of claim 14 further comprising:
electrical contact pad surfaces of the first integrated circuit die wire bonded to electrical contact pad surfaces of the substrate material;
electrical contact pad surfaces of the interposer wire bonded to electrical contact pad surfaces of the first integrated circuit die; and
electrical contact pad surfaces of the second integrated circuit die wire bonded to electrical contact pad surfaces of the interposer.

16. An interposer for an integrated circuit package comprising:
a substrate frame portion defining an opening adapted to receive an integrated circuit die having at least one electrical contact pad surface located on a top surface of the integrated circuit die; and
at least one electrical contact pad surface located on a top surface of the substrate frame portion.

17. The interposer of claim 16, wherein the substrate frame portion includes at least four walls that define the opening.

18. The interposer of claim 16, wherein the opening corresponds in shape to a shape of the integrated circuit die.

19. The interposer of claim 16, wherein at least one electrical contact pad surface of the integrated circuit die is wire bonded to at least one electrical contact pad surface of the interposer.

20. An interposer for an integrated circuit package comprising:
a substrate frame portion defining an opening adapted to receive an integrated circuit die; and
at least one pair of electrical contact pad surfaces located on a top surface of the substrate frame portion, wherein each of the at least one pair of electrical contact pad surfaces comprises a first electrical contact pad surface operatively coupled to a second electrical contact pad surface.

21. The interposer of claim 20, wherein each first electrical contact pad surface is wire bonded to a electrical contact pad surface located on a top surface of the integrated circuit die, and wherein each second electrical contact pad surface is wire bonded to a electrical contact pad surface of a second integrated circuit.
